(19) United States
(12) Patent Application Publication
(10) Pub. No.: US 2024/0088288 A1
(43) Pub. Date: Mar. 14, 2024

(54) VERTICAL GAN POWER TRANSISTOR UNIT CELL, VERTICAL GAN POWER TRANSISTOR AND METHOD FOR PRODUCING A VERTICAL GAN POWER TRANSISTOR UNIT CELL

(71) Applicant: Robert Bosch GmbH, Stuttgart (DE)

(72) Inventor: Jens Baringhaus, Sindelfingen (DE)

(21) Appl. No.: 18/466,180

(22) Filed: Sep. 13, 2023

(30) Foreign Application Priority Data
Sep. 14, 2022 (DE) 10 2022 209 606.1

(51) Int. Cl. H01L 29/78; H01L 29/06; H01L 29/10; H01L 29/20

(52) U.S. Cl. CPC H01L 29/7813; H01L 29/0623; H01L 29/1095; H01L 29/2003

(57) ABSTRACT

Vertical GaN power transistor unit cell. The vertical GaN power transistor unit cell including a drift layer and at least one field shielding region. The at least one field shielding region is regionally disposed in the drift layer and includes an intrinsically p-type material.

### FIELD

The present invention relates to a vertical GaN power transistor unit cell, a vertical GaN power transistor and a method for producing a vertical GaN power transistor unit cell.

### BACKGROUND INFORMATION

Gallium nitride-based power semiconductor components are characterized by a high breakdown field strength. This requires field shielding regions.

The disadvantage here is that doping of gallium nitride is difficult.

An object of the present invention is to overcome this disadvantage.

### SUMMARY

A vertical GaN power transistor unit cell comprises a drift layer and at least one field shielding region. According to an example embodiment of the present invention, the at least one field shielding region is disposed in the drift layer and comprises an intrinsically p-type material.

An advantage of this is that the shielding regions are implant-free.

In one example embodiment of the present invention, the intrinsically p-type material comprises a transition metal oxide, in particular ZnO or NiO.

An advantage of this is that the production of the field shielding region is cost-efficient.

In a further development of the present invention, the at least one field shielding region is disposed below a first trench, wherein the first trench extends into the drift layer and a gate electrode is disposed inside the first trench, wherein the at least one field shielding region is electrically insulated from a gate dielectric by means of an insulation region.

An advantage of this is that a superjunction effect is achieved in the drift zone, and only one trench is needed inside the transistor unit cell.

In a further embodiment of the present invention, a first trench and second trenches extend into the drift layer, wherein the first trench and the second trenches are disposed spaced apart parallel to one another, wherein the second trenches are deeper than the first trench, wherein the at least one field shielding region is disposed inside the second trenches and a source electrode is disposed on the at least one field shielding region.

An advantage of this is that electrical fields can be effectively shielded in the event of a short-circuit.

In one further development of the present invention, the second trenches extend at least into a lower third of the drift layer.

An advantage of this is that the drift zone is completely depleted in the blocking case.

According to an example embodiment of the present invention, a vertical GaN power transistor comprises a plurality of GaN power transistor unit cells. According to the present invention, an edge termination is provided which comprises at least one third trench, wherein a further field shielding region comprising the intrinsically p-type material is disposed inside the third trench.

An advantage of this is that field peaks are avoided or reduced in the edge region of the power semiconductor component.

In one further development of the present invention, the edge termination comprises a plurality of third trenches, wherein the third trenches have different lateral distances from one another.

An advantage here is that this results in a modulation of the charge carrier density in the edge region.

In a further embodiment of the present invention, regions comprising compensation doping are disposed between the third trenches.

An advantage of this is that the shielding effect in the edge region of the power semiconductor component is optimal.

The method according to an example embodiment of the present invention for producing a vertical GaN power transistor unit cell which comprises a drift layer includes creating at least one field shielding region by means of sputtering, wherein the field shielding region is disposed in the drift layer and comprises intrinsically p-type material.

An advantage of this is that producing the vertical GaN power transistor unit cell is simple.

Further advantages will emerge from the following description of embodiment examples and the disclosure herein.

### BRIEF DESCRIPTION OF THE DRAWINGS

The present invention is explained in the following with reference to preferred embodiments and the figures.

FIG. 1 shows a vertical GaN power transistor unit cell according to an example embodiment of the present invention.

FIG. 2 shows another vertical GaN power transistor unit cell according to an example embodiment of the present invention the present invention.

FIG. 3 shows a section of a vertical GaN power transistor with an edge termination, according to an example embodiment of the present invention.

FIG. 4 shows a method for producing a vertical GaN power transistor unit cell, according to an example embodiment of the present invention.

### DETAILED DESCRIPTION OF EXAMPLE EMBODIMENTS

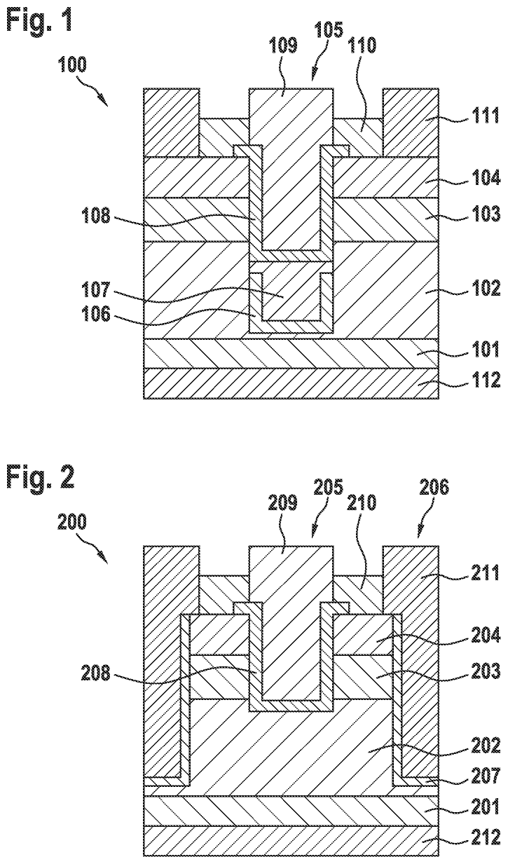

FIG. 1 shows a vertical GaN power transistor unit cell 100 according to the present invention. The term “power transistor unit cell” is understood here to be a unit cell comprising gate, drain and source connections. The vertical GaN power transistor unit cell 100 comprises a drain region 101. The drain region 101 has a high level of n-doping. A drift layer 102 is disposed on the drain region 101. The drift layer 102 has a much lower level of n-doping than the drain region 101. Channel regions 103 are disposed on the drift layer 102. The channel regions 103 are p-doped. Source regions 104 are disposed on the channel region 103. The source regions 104 have a high level of n-doping. Starting from an upper side of the source regions 104, a first trench 105 extends into the drift layer 102. The first trench 105 includes a field shielding region 106, wherein the field shielding region 106 is disposed inside the drift layer 102. The first trench 105 is filled with an insulation material to a specific height inside the drift layer 102 above the field shielding region 106, wherein the insulation material forms an insulation region 107. The insulation material includes SiO₂ or SiN, for example. A gate dielectric 108 is disposed inside the first trench 105 above the insulation region 107. A gate electrode 109 is disposed on the gate dielectric 108. Further insulation regions 110 and source electrodes 111 are disposed on the source regions 104. A drain electrode 112 is disposed below the drain region 101. The field shielding region 106 is electrically connected to the source electrodes 111 outside the power transistor unit cell.

FIG. 2 shows another vertical GaN power transistor unit cell 200 according to the present invention, which comprises a drain region 201 having a high level of n-doping. A drift layer 202 is disposed on the drain region 201. The drift layer 202 has a much lower level of n-doping than the drain region 201. Channel regions 203, which are p-doped, are disposed on the drift layer 202. Source regions 204 are disposed on the channel region 203. The source regions 204 have a high level of n-doping. Starting from an upper side of the source regions 204, a first trench 205 extends into the drift layer 202. The first trench 205 comprises a gate dielectric 208. A gate electrode 209 is disposed on the gate dielectric 208 inside the first trench 205. Starting from the upper side of the source regions 204, second trenches 206 extend into the drift layer 202 laterally spaced apart from and Substitute Specification parallel to the first trench 205. The second trenches 206 have the same depth or a greater depth than the first trench 205. The second trenches 206 comprise a field shielding region 207 disposed on a trench surface. In one embodiment example, the second trenches 206 extend into the lower third of the drift layer 202. This creates a superjunction effect in the drift layer 202 during operation of the power transistor unit cell 200. The number of p-type charge carriers, i.e. holes, of the p-conductive region is selected such that the drift zone is completely electrically depleted in the blocking case. As an alternative to adjusting the holes, it is also possible to vary the doping of the drift zone or the distance between the p-conductive regions to achieve this depletion. In another embodiment example, the second trenches 206 extend to an upper side of the drain region 201. Further insulation regions 210 and source electrodes 211 are disposed on the source regions 204. A drain electrode 212 is disposed below the drain region 201. The field shielding region 207 is electrically contacted via the source electrodes 211.

The field shielding region 106 and 207 comprises intrinsically p-doped material, for example oxides of transition metals from the fourth period of the periodic table, for example ZnO or NiO.

A vertical GaN power transistor comprises a plurality of vertical GaN power transistor unit cells 100 and 200.

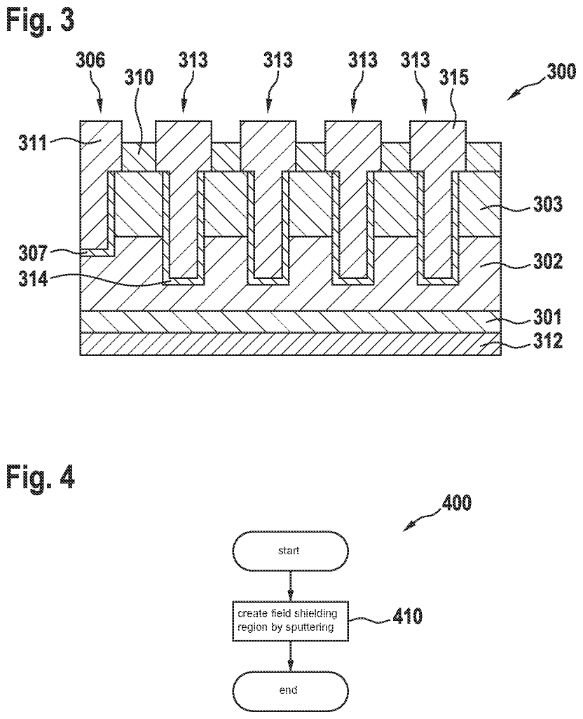

FIG. 3 shows a section 300 of a vertical GaN power transistor with an edge termination. The shown vertical GaN power transistor comprises a plurality of vertical GaN power transistor unit cells of FIG. 2. The vertical GaN power transistor can alternatively also comprise a plurality of vertical GaN power transistor unit cells of FIG. 1.

The section 300 of the vertical GaN power transistor shows a drain region 301 on which a drift layer 302 is disposed. Regions 303, which are preferably p-doped, are disposed on the drift layer 302. The regions 303 are alternatively p-doped and n-doped in some areas and serve to compensate charge carriers in the edge region. The section 300 shows a second trench 306. The second trench 306 comprises an intrinsically p-conductive field shielding region 307. A source electrode 311 is disposed on the field shielding region 307. A plurality of third trenches 313 are disposed respectively laterally spaced apart from one another and laterally horizontally spaced apart from the second trench 306. The distance between the third trenches 313 can thus be different. The third trenches 313 have a greater depth than the second trenches 306. The third trenches 313 each comprise a further field shielding region 314, which is likewise intrinsically p-conductive. The further field shielding region 314 can comprise the same material as the field shielding region 307. The third trenches 313 are filled with a further material 315 that is connected to the source electrode 311 in an electrically conductive manner. Alternatively, a single wide and deep third trench 313 can be disposed laterally horizontally spaced apart from the second trench 306. The third trench 313 typically has 1.2 times to twice the depth of the second trench 306. The width of the third trench 313 is typically at least a factor of 10 greater than that of the second trench 306.

The vertical GaN power transistors 300 are used in the electric drive train of electric or hybrid vehicles, in chargers and DC/DC converters for electric or hybrid vehicles, and in inverters for household appliances like washing machines.

FIG. 4 shows a method 400 for producing a vertical GaN power transistor unit cell. The method comprises a step 410, in which at least one field shielding region is created by means of sputtering, wherein the at least one field shielding region comprises intrinsically p-type material. The remaining production steps are based on the related art.

1-9. (canceled)

10. A vertical GaN power transistor unit cell, comprising
a drift layer; and
at least one field shielding region regionally disposed in the drift layer and including an intrinsically p-type material.

11. The vertical GaN power transistor unit cell according to claim 10, wherein the intrinsically p-type material including a transition metal oxide.

12. The vertical GaN power transistor unit cell according to claim 11, wherein the transition metal oxide is NiO or ZiO.

13. The vertical GaN power transistor unit cell according to claim 10, wherein the at least one field shielding region is disposed below a first trench, wherein the first trench extends into the drift layer and a gate electrode is disposed inside the first trench, wherein the at least one field shielding region is electrically insulated from a gate dielectric by an insulation region.

14. The vertical GaN power transistor unit cell according to claim 10, wherein a first trench and second trenches extend into the drift layer, wherein the first trench and the second trenches are disposed spaced apart parallel to one another, wherein the second trenches are deeper than the first trench, wherein the at least one field shielding region is disposed inside the second trenches and a source electrode is disposed on the at least one field shielding region.

15. The vertical GaN power transistor unit cell according to claim 14, wherein the second trenches extend at least into a lower third of the drift layer.

16. A vertical GaN power transistor, comprising:
a plurality of vertical GaN power transistor unit cells, each including:
a drift layer, and
at least one field shielding region regionally disposed in the drift layer and including an intrinsically p-type material; and
an edge termination which includes at least one third trench, wherein a further field shielding region including the intrinsically p-type material is disposed inside the third trench.

17. The vertical GaN power transistor according to claim 16, wherein the edge termination includes a plurality of third trenches, wherein the third trenches have different lateral distances from one another.

18. The vertical GaN power transistor according to claim 17, wherein regions including compensation doping are disposed between the third trenches.

19. A method for producing a vertical GaN power transistor unit cell with a drift layer, the method comprising the following:
creating at least one field shielding region by sputtering, wherein the field shielding region is regionally disposed in the drift layer and includes intrinsically p-type material.
